(19) United States
(12) Patent Application Publication
(10) Pub. No.: US 2026/0324321 A1
(43) Pub. Date: Oct. 15, 2026

(54) METHOD FOR ETCHING FEATURES IN A STACK

(71) Applicant: Lam Research Corporation, Fremont, CA (US)

(72) Inventors: Eric HUDSON, Berkeley, CA (US); Leonid BELAU, Pleasanton, CA (US)

(21) Appl. No.: 19/157,636

(22) PCT Filed: Feb. 22, 2024
(86) PCT No.: PCT/US2024/016916

§ 371 Date: Aug. 18, 2025

Related U.S. Application Data
(60) Provisional application No. 63/448,049, filed on Feb. 24, 2023.

(51) Int. Cl. H10P 50/28; H01J 37/32; H10P 50/00; H10P 72/00

(52) U.S. Cl. CPC H10P 50/283; H01J 37/32449; H01J 37/32724; H10P 50/73; H10P 72/0421; H01J 2237/002; H01J 2237/3341

(57) ABSTRACT

A method for etching features in a stack comprising a silicon oxide layer below a mask is provided. A substrate support for supporting the stack in an etch chamber is cooled to a temperature below 0 °C. An etch gas is provided comprising a halogen containing component and a phosphorus containing component. A plasma is generated from the etch gas. A bias is provided to accelerate ions from the plasma to the stack. Features are selectively etched in the stack with respect to the mask.

### CROSS-REFERENCE TO RELATED APPLICATION

This application claims the benefit of priority of U.S. Application No. 63/448,049, filed Feb. 24, 2023, which is incorporated herein by reference for all purposes.

### BACKGROUND

The disclosure relates to a method of forming semiconductor devices on a semiconductor wafer. More specifically, the disclosure relates to etching a stack in the formation of memory or other semiconductor devices.

In forming semiconductor devices, etch layers may be etched to form memory holes or lines. Some semiconductor devices may be formed by etching a stack of bilayers of silicon oxide and silicon nitride (ONON). Such stacks may be used in memory applications, such as in forming dynamic random access memory (DRAM) and three dimensional “negative and” gates (3D NAND).

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, a method for etching features in a stack comprising a silicon oxide layer below a mask is provided. A substrate support for supporting the stack in an etch chamber is cooled to a temperature below 0 °C. An etch gas is provided comprising a halogen containing component and a phosphorous containing component. A plasma is generated from the etch gas. A bias is provided to accelerate ions from the plasma to the stack. Features are selectively etched in the stack with respect to the mask.

In another manifestation, an apparatus for processing a stack over a substrate with at least one silicon oxide layer is provided. An etch chamber has a substrate support for supporting a substrate inside the etch chamber. A temperature controller controls a temperature of the substrate support. A gas source provides an etch gas into the etch chamber. The gas source comprises a halogen containing component source and a phosphorus containing component source. An electrode provides power to the etch gas. A power source provides power to the electrode.

In another manifestation, a method for etching features in a stack comprising a silicon oxide layer below a mask is provided. A substrate support for supporting the stack in an etch chamber is cooled to a temperature below 0 °C. An etch gas is provided comprising a halogen containing component and a phosphorus containing component. A multi-state power with at least three states is provided, wherein the multi-state power generates a plasma from the etch gas and provides a bias to accelerate ions from the plasma to the stack. Features are selectively etched in the stack with respect to the mask.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart that may be used in some embodiments.

FIGS. 2A-B are schematic cross-sectional views of a stack processed according to an embodiment.

FIG. 3 is a schematic view of an etch chamber that may be used in an embodiment.

FIG. 4 is a schematic view of a computer system that may be used in practicing an embodiment.

FIG. 5 is a high level flow chart that may be used in some embodiments.

FIG. 6A of a clock signal used in some embodiments.

FIG. 6B graph of a digital pulsed signal used in some embodiments.

FIG. 6C graph that illustrates RF signals that are used in some embodiments.

FIG. 7 is a schematic view of another etch chamber that may be used in some embodiments.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

There is a significant challenge to control profile in the very high aspect ratio contact dielectric etch, specifically during cryogenic etching of 3D NAND pillar structure: large bow CD with small bottom CD. This is likely due to increased by-product accumulation close to the etch front that slows down a SiO₂ reactive ion etch (RIE). The most common method to increase the etch rate (ER) for a high aspect ratio is to increase ion energy and ion flux. This results in worse bow CD control (larger bow). Another common practice to increase bottom CD and ER is modifying plasma chemistry. This approach causes other tradeoffs such as bow enlargement, capping, or excessive contact twisting.

In some embodiments, the etch front surface is modified to enhance the etching of silicon oxide (SiO₂, also known as SiO) and silicon nitride (Si₃N₄, also known as SiN). Some embodiments add phosphorus (P) containing precursors to a plasma. It is believed that P containing precursors cause P-doping of the SiO₂ and Si₃N₄ material. Doped SiO₂ material will have reduced activation energy for RIE. Thus even low energy ions from the plasma can contribute to the etch. Phosphine (PH₃) and phosphorus trifluoride (PF₃) are the two major compounds that can be used in some embodiments as P containing precursors. Some embodiments may use other compounds such as phosphorus trichloride (PCl₃), phosphorus tribromide (PBr₃), phosphorus oxyfluoride (POF₃), or phosphorus triiodide (PI₃), which are liquid or solid at room temperature and therefore are harder to productize. Some embodiments may use phosphorus pentafluoride (PF₅).

Reduction of the etch activation energy of SiO₂ and Si₃N₄ by phosphorus doping for RIE will help to maintain a high ONON pillar ER even at a high aspect ratio. This will enable more efficient utilization of reactive ions delivered to the etch front. Some embodiments make the silicon oxide etch more chemical in nature and more similar to a silicon nitride etch, providing a more uniform ONON etching. In some embodiments, boron may be used to provide boron doping for RIE.

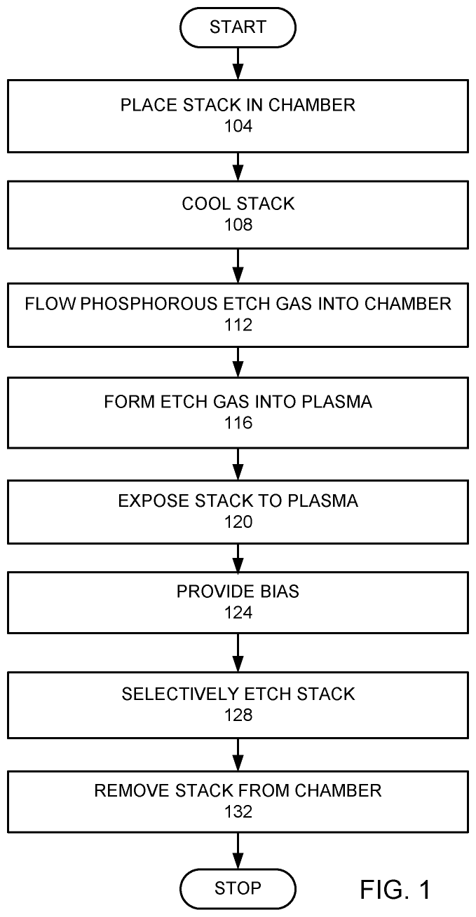

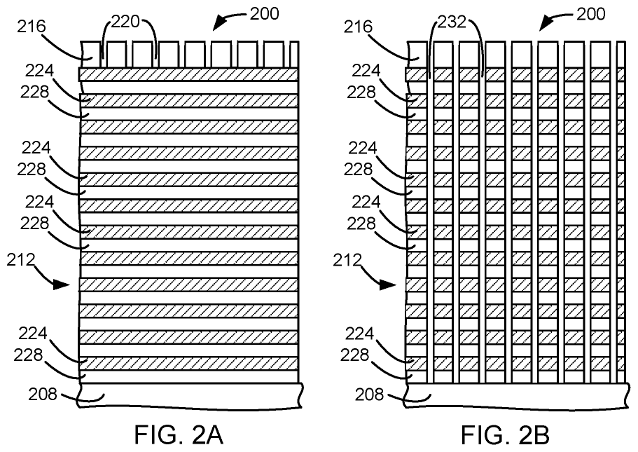

To facilitate understanding, FIG. 1 is a high level flow chart that may be used in some embodiments. In some embodiments, a stack is placed in an etch chamber on a substrate support (step 104). In some embodiments, the stack is disposed below a carbon containing patterned mask. In some embodiments, the carbon containing mask is an amorphous carbon mask. FIG. 2A is a schematic cross-sectional view of a stack 200 used in an embodiment. In some embodiments, the stack comprises a substrate 208 under a plurality of bilayers 212, which is disposed below a carbon containing patterned mask 216. One or more layers may be disposed between the substrate 208 and the plurality of bilayers 212 or the plurality of bilayers 212 and the carbon containing patterned mask 216. However, some embodiments do not have a silicon containing mask above the plurality of bilayers 212 or above the carbon containing patterned mask 216. The carbon containing patterned mask 216 may be amorphous carbon. In some embodiments, the patterned mask pattern provides mask features 220 for high aspect ratio contacts. In some embodiments, the mask features are formed before the substrate is placed in the etch chamber. In other embodiments, the mask features 220 are formed while the substrate is in the etch chamber. In some embodiments, the plurality of bilayers 212 are bilayers of a layer of silicon oxide 224 and a layer of silicon nitride 228.

After the stack 200 has been placed into an etch chamber, the stack is cooled by providing a chiller temperature below 0 (step 108). The chiller cools a coolant that cools the stack 200. In some embodiments, the chiller is cooled to a temperature below −40°.

An etch gas comprising a halogen containing component and a phosphorus containing component is provided (step 112). In some embodiments, the etch gas is flowed into the etch chamber. In some embodiments, the etch gas comprises a halogen containing component, a phosphorus containing component, a hydrogen containing component, a hydrocarbon containing component, and a fluorocarbon containing component. In some embodiments, the halogen containing component comprises at least one of a bromofluorocarbon CₓBr_{y}F_{z}, a chlorofluorocarbon CₓCl_{y}F_{z}, a chlorohydrocarbon CₓH_{y}Cl_{z}, a bromohydrocarbon CₓH_{y}Br_{z}, a fluorohydrocarbon CₓH_{y}F_{z}, a fluorocarbon CₓF_{y}, silicon tetrachloride (SiCl₄), bromine trichloride (BCl₃), nitrogen trifluoride (NF₃), C₄F₈, octafluoropropane (C₃F₈), hexafluoro-1,3-butadiene (C₄F₆), sulfur hexafluoride (SF₆), carbon tetrafluoride (CF₄), chlorine (Cl₂), hydrogen bromide (HBr), trifluoroiodomethane (CF₃I), fluoromethane (CH₃F), difluoromethane (CH₂F₂), hydrochloric acid (HCl), and trifluoromethane (CHF₃). In some embodiments, the halogen containing component is a metal halide. In some embodiments, the etch gas further comprises at least one of methane (CH₄), hydrogen fluoride (HF), and hydrogen gas (H₂). In some embodiments, the etch gas further comprises an inert gas, such as argon (Ar), helium (He), krypton (Kr), neon (Ne), xenon (Xe), or nitrogen (N₂). In some embodiments, the inert gas provides ions for ion bombardment to facilitate etching and therefore may be an inert bombardment gas. In some embodiments, the etch gas is oxygen free and free from both octafluorocyclobutane (C₄F₈) and hexafluorocyclobutene (C₄F₆). In some embodiments, the etch gas further comprises at least one of methane (CH₄), and hydrogen gas (H₂). In some embodiments, the phosphorus containing component is at least one of PF₅, PH₃, PF₃, PCl₃, PBr₃, POF₃, and PI₃. In some embodiments, an example of an etch gas is 5-120 sccm NF₃, 50-400 sccm H₂, 0-100 sccm CH₃F, 1-100 sccm PH₃, 0-100 sccm Cl₂, 0-100 sccm HBr, and 20-200 sccm CH₂F₂. In this example, a pressure of 5 to 60 mTorr is provided. In some embodiments, the halogen containing component may comprise a fluorine, chlorine, or bromine containing component.

The etch gas is formed into an etch plasma (step 116). This may be accomplished by providing an excitation RF with a frequency of 60 megahertz (MHz) at 200 to 15000 watts. In some embodiments, the RF power is in the range of 0 to 25000 watts at a frequency of 60 MHz. The stack 200 is exposed to the plasma (step 120). A bias with a magnitude in the range of 200 volts to 15000 volts is provided (step 124). In some embodiments, the bias power is at least 200 volts. In some embodiments, an RF power that is either continuous or pulsed RF power with a peak power in the range of 3 kW to 150 kW may be used for both excitation RF power using a higher frequency and bias RF power using a lower frequency. The bias causes ions to be accelerated to the stack 200 causing the selective etching of high aspect ratio etch features into the stack 200 with respect to the carbon containing patterned mask (step 128). In some embodiments, the bias is provided by a pulsed bias of at least two states where the bias source is a pulsed bias source. The bias source may comprise a primary pulsed bias source and a secondary pulsed bias source. In some embodiments, the bias is provided by the RF power source. The plasma is maintained for 180 to 3600 seconds. The etch is able to etch both the silicon oxide and silicon nitride layers. After the etch is completed, the substrate is then removed from the etch chamber (step 132).

FIG. 2B is a cross-sectional view of the stack 200 after the contacts 232 have been etched. The contacts are high aspect ratio contacts. Preferably, the contacts have an etch depth to feature CD width aspect ratio of greater than 30:1. More preferably, the high aspect ratio contacts have a height to CD width ratio of greater than 40:1. More preferably, the high aspect ratio contacts have a height to CD width ratio of greater than 100:1.

The etch process is able to selectively etch the silicon oxide and silicon nitride layers with respect to amorphous carbon with a selectivity of greater than 3:1 while etching high aspect ratio features. The resulting features also have reduced bowing, striation, distorting, capping, and tapering. In addition, this embodiment allows the use of a carbon containing patterned mask, such as amorphous carbon, without requiring a silicon containing mask such as polysilicon, resulting in reduced costs and defects.

Previous processes that use an etch, where the stack is processed at a temperature above 0 °C, relied on a fluorocarbon chemistry to etch and provide sidewall protection. Such a process resulted in a mask to silicon oxide and silicon nitride etch selectivity of less than 3:1. Sidewall protection was provided by polymer deposition, which is controlled by the concentration of carbon, where a higher concentration of carbon increases sidewall deposition, and by oxygen, where a higher concentration of oxygen consumes the deposited polymer. The higher concentration of oxygen also increased the consumption of the mask. Some previous processes used a silicon containing mask.

Some embodiments increase the etch rate and improve contact shape/striation compared to a conventional approach. Without being bound by theory, it is believed that the addition of a phosphorus containing component to the etch gas causes phosphorus dopant to deposit in the silicon oxide and silicon nitride containing layers. The phosphorus dopant lowers the activation energy required to etch the silicon oxide containing layers so that silicon oxide is more easily etched and so that lower energy ions are more efficient. Providing lower energy ions for etching results in less bowing and the reduction of other etch complications caused by high energy ions. The phosphorus dopant may also lower the activation energy required to etch silicon nitride. However, the phosphorus dopant lowers the activation energy for silicon oxide more than the phosphorus lowers the activation energy for silicon nitride. In the prior art, silicon oxide was slower to etch than silicon nitride, causing an uneven etch of ONON stacks. Providing the phosphorus dopant allows for a more even etch of ONON.

In some embodiments, the electrostatic chuck is cooled to a temperature below 0 °C. In some embodiments, the chuck is cooled to a temperature below −10 °C. In some embodiments, the chuck is cooled to a temperature below −20 °C. In some embodiments, the chuck is cooled to a temperature between −80 °C to 0 °C to provide an improved process. In some embodiments, the stack is cooled to a temperature between −60 °C to −20 °C.

In some embodiments, the stack comprises one or more layers of at least one of silicon oxide and silicon nitride. In some embodiments, the stack is a single layer of silicon oxide or silicon nitride. In some embodiments, the silicon oxide and/or silicon nitride layers are doped. In some embodiments, the silicon oxide and/or silicon nitride layers are undoped. In some embodiments, the stack comprises alternating layers of silicon oxide and polysilicon (OPOP).

In some embodiments, the ONON stack may be etched to form contact holes, channel holes, or trenches in making a 3D NAND memory device. Other embodiments may etch OPOP (alternating layers of SiO₂ and polysilicon) stacks to form contact holes, channel holes, or trenches in making 3D NAND memory devices. Other embodiments may be used for DRAM Capacitor etching. The capacitor etch may have a depth of 1.5 microns with a tight CD providing a high aspect ratio feature in silicon oxide. Some embodiments provide etch features with a height to width ratio greater than 10:1. Some embodiments provide for a CD less than 50 nm with an etch depth of greater than 20 microns, providing features with a depth to width aspect ratio of at least 4000:1. In some embodiments, the etch depth is greater than 3 microns. Some embodiments allow the etching of at least 192 or 256 bilayers of silicon oxide and silicon nitride in a single etch step using a single amorphous carbon mask with a thickness of less than 1 micron.

In some embodiments, the etch gas may comprise at least one of Cl₂ and HBr as the halogen containing component and PFs as the phosphorus containing component.

In some embodiments, the providing the etch gas and the ion etching may be provided as sequential steps in a cyclical process. Providing the etch gas simultaneously with the ion etching may provide a faster process than the sequential cyclical process.

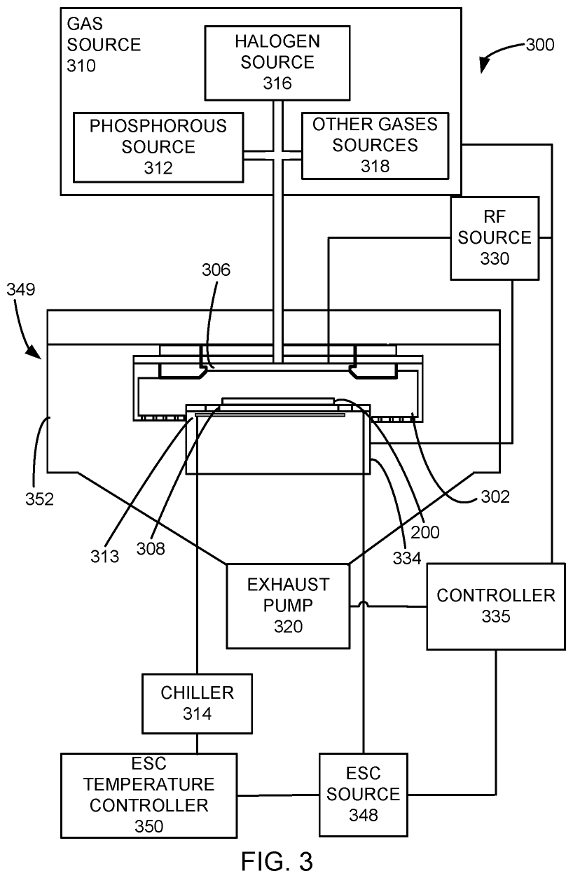

FIG. 3 is a schematic view of an etch reactor that may be used in an embodiment. In one or more embodiments, an etch reactor 300 comprises a gas distribution plate 306 providing a gas inlet and an electrostatic chuck (ESC) 308, within an etch chamber 349, enclosed by a chamber wall 352. Within the etch chamber 349, a stack 200 is positioned over the ESC 308, where the ESC 308 acts as a substrate support. The ESC 308 may provide a bias from the ESC source 348. An etch gas source 310 is connected to the etch chamber 349 through the gas distribution plate 306. In some embodiments, the etch gas source 310 comprises a phosphorus containing component source 312, a halogen containing component source 316, and a source of other gases 318, such as a hydrogen containing component source, and a fluorocarbon containing component source. An ESC temperature controller 350 is connected to a chiller 314. The chiller 314 is able to cool the ESC 308 to a temperature of less than 0 °C. In this embodiment, the chiller 314 provides a coolant to channels 313 in or near the ESC 308. A radio frequency (RF) power source 330 provides RF power to a lower electrode and/or an upper electrode, which in this embodiment are the ESC 308 and the gas distribution plate 306. In an exemplary embodiment, 400 kilohertz (kHz), 60 megahertz (MHz), and optionally 2 MHz, and 27 MHz power sources make up at least a primary power source and a secondary power source of the RF power source 330 and the ESC source 348. In this embodiment, the upper electrode is grounded. In this embodiment, one generator is provided for each frequency. In other embodiments, the generators may be in separate RF sources, or separate RF generators may be connected to different electrodes. For example, the upper electrode may have inner and outer electrodes connected to different RF sources. Other arrangements of RF sources and electrodes may be used in other embodiments. The RF power may be continuous or pulsed. A portion or all of the RF power may be delivered using non-sinusoidal waveforms. A controller 335 is controllably connected to the RF power source 330, the ESC source 348, an exhaust pump 320, and the etch gas source 310. An example of such an etch chamber is the Exelan Flex® dielectric etch system or Vantex® dielectric etch system manufactured by Lam Research Corporation of Fremont, CA. The etch chamber can be a CCP (capacitively coupled plasma) reactor or an ICP (inductively coupled plasma) reactor, where the electrode may be a coil.

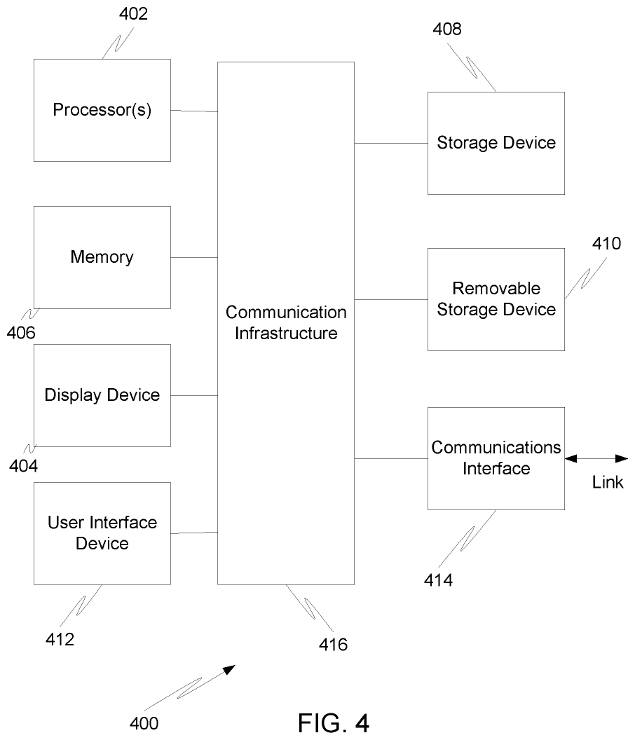

FIG. 4 is a high level block diagram showing a computer system 400, which is suitable for implementing a controller 335 used in embodiments. The computer system may have many physical forms ranging from an integrated circuit, a printed circuit board, and a small handheld device up to a huge supercomputer. The computer system 400 includes one or more processors 402 and further can include an electronic display device 404 (for displaying graphics, text, and other data), a main memory 406 (e.g., random access memory (RAM)), a storage device 408 (e.g., hard disk drive), removable storage device 410 (e.g., optical disk drive), user interface devices 412 (e.g., keyboards, touch screens, keypads, mice or other pointing devices, etc.), and a communication interface 414 (e.g., wireless network interface). The communication interface 414 allows software and data to be transferred between the computer system 400 and external devices via a link. The system may also include a communications infrastructure 416 (e.g., a communications bus, cross-over bar, or network) to which the aforementioned devices/modules are connected.

The information transferred via communications interface 414 may be in the form of signals such as electronic, electromagnetic, optical, or other signals capable of being received by communications interface 414, via a communication link that carries signals and may be implemented using wire or cable, fiber optics, a phone line, a cellular phone link, a radio frequency link, and/or other communication channels. With such a communications interface, it is contemplated that the one or more processors 402 might receive information from a network or might output information to the network in the course of performing the above-described method steps. Furthermore, method embodiments may execute solely upon the processors or may execute over a network such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer readable code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

In some embodiments, liquid nitrogen is used as a coolant that is flowed through the ESC 308 to provide cooling. In other embodiments, liquid Vertel Sinera™ manufactured by DuPont Corporation of Wilmington, DE may be used as the coolant.

In some embodiments, RF power is provided using a multi-state pulsing with at least three states, where the multi-state pulsing generates a plasma from the etch gas and provides a bias. In some embodiments, the multi-state pulsing has at least a primary RF signal at a first frequency range and a secondary RF signal in a second frequency range, where both the primary RF signal and the secondary RF signal are pulsed between at least a first state, a second state, and a third state. In some embodiments, one or more of the RF signals are non-sinusoidal waveforms.

In some embodiments, in a first state, the primary RF signal is at a first primary power level and the secondary RF signal is at a first secondary power level, in a second state the primary RF signal is at a second primary power level and the secondary RF signal is at the second secondary power level, and in a third state the primary RF signal is at a third primary power level and the secondary RF signal is at a third secondary power level. In some embodiments, in a first state, the primary RF signal is at a first primary power level and the secondary RF signal is at a first secondary power level, in a second state the primary RF signal is at a second primary power level and the secondary RF signal is at the second secondary power level, and in a third state no RF power is supplied. In some embodiments, the first primary power level is greater than the first secondary power level and the second primary power level is less than the second secondary power level where the absolute value of a difference between the third primary power level and the third secondary power level is less than both the absolute value of a difference between the first primary power and the first secondary power and the absolute value of a difference between the second primary power and the second secondary power.

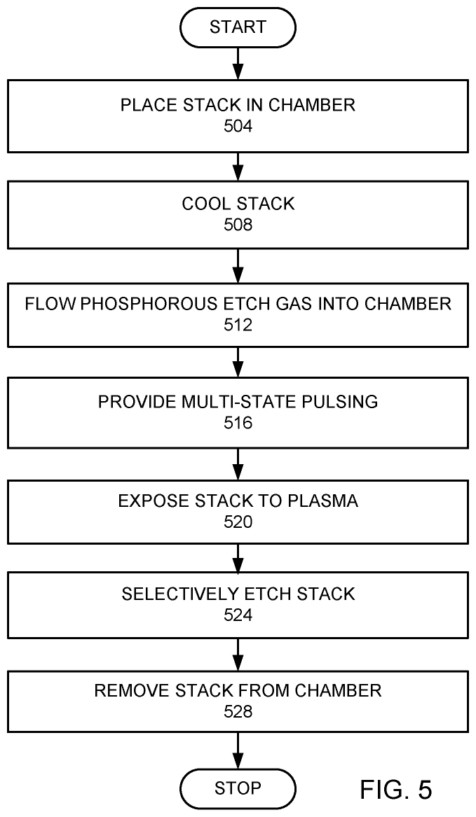

FIG. 5 is a flow chart of a process that uses multi-state pulsing that may be used in some embodiments. A stack is placed in a chamber (step 504). In some embodiments, the stack may be the stack 200 shown in FIG. 2A. After the stack 200 has been placed into an etch chamber, the stack is cooled to a temperature below 0 ° (step 508). In some embodiments, the stack is cooled to a temperature below −40 °.

An etch gas comprising a halogen containing component and a phosphorus containing component is flowed into the etch chamber (step 112). In some embodiments, the etch gas comprises a halogen containing component, a phosphorus containing component, a hydrogen containing component, a hydrocarbon containing component, and a fluorocarbon containing component. In some embodiments, the halogen containing component comprises at least one of a bromofluorocarbon CₓBr_{y}F_{z}, a chlorofluorocarbon CₓCl_{y}F_{z}, chlorohydrocarbon CₓH_{y}Cl_{z}, a bromohydrocarbon CₓH_{y}Br_{z}, a fluorohydrocarbon CₓH_{y}F_{z}, a fluorocarbon CₓF_{y}, silicon tetrachloride (SiCl₄), bromine trichloride (BCl₃), nitrogen trifluoride (NF₃), C₄F₈, octafluoropropane (C₃F₈), hexafluoro-1,3-butadiene (C₄F₆), sulfur hexafluoride (SF₆), carbon tetrafluoride (CF₄), chlorine (Cl₂), hydrogen bromide (HBr), trifluoroiodomethane (CF₃I), fluoromethane (CH₃F), difluoromethane (CH₂F₂), hydrochloric acid (HCl), and trifluoromethane (CHF₃). In some embodiments, the halogen containing component is a metal halide. In some embodiments, the etch gas further comprises an inert gas, such as argon (Ar), helium (He), krypton (Kr), neon (Ne), xenon (Xe), or nitrogen (N₂). In some embodiments, the inert gas provides ions for ion bombardment to facilitate etching and therefore may be an inert bombardment gas. In some embodiments, the etch gas is oxygen free and free from both octafluorocyclobutane (C₄F₈) and hexafluorocyclobutene (C₄F₆). In some embodiments, the etch gas is oxygen free and carbon free. In some embodiments, the etch gas further comprises at least one of methane (CH₄), hydrogen fluoride (HF), and hydrogen gas (H₂). In some embodiments, the phosphorus containing component is at least one of PF₅, PH₃, PF₃, PCl₃, PBr₃, POF₃, and PI₃. In some embodiments, an example of an etch gas is 0-120 sccm NF₃, 0-400 sccm H₂, 1-100 sccm PF₅. 0-100 sccm Cl₂, 0-100 sccm HBr, 0-250 sccm HF, and 0-200 sccm CHF₂. In this example, a pressure of 5 to 60 mTorr is provided. In some embodiments, the halogen containing component may comprise a fluorine, chlorine, or bromine containing component. In some embodiments, boron trifluoride (BF₃) or boron trichloride (BCl₃) may be used.

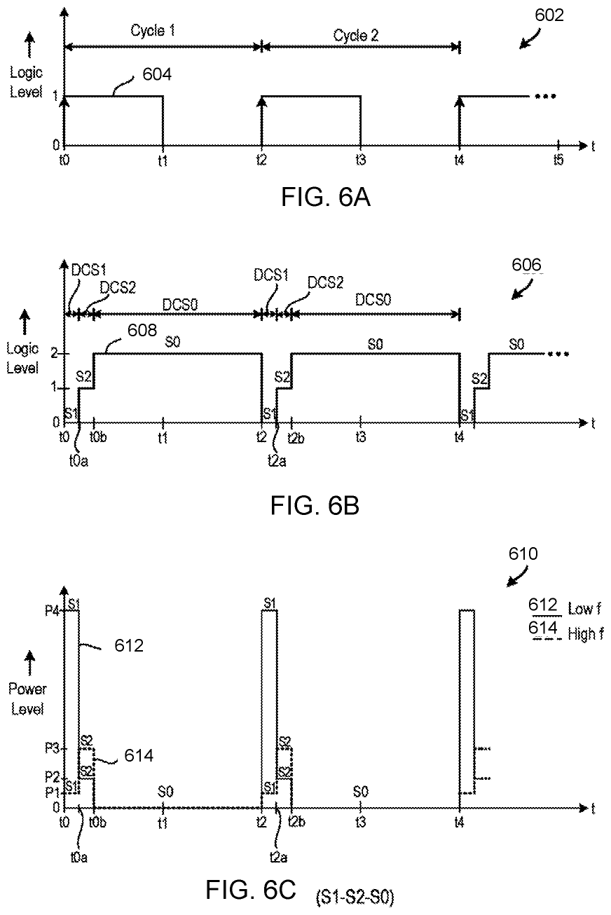

Multi-state pulsing is provided (step 516). In some embodiments, the multi-state pulsing of any of the states may have a duty cycle in the range of 1% to 99%. FIG. 6A is a graph 602 of a clock signal 604 that is used to provide the multi-state pulsing in some embodiments. The graph 602 plots a logic level on a y-axis and a time t on an x-axis. The y-axis of the graph 602 includes a logic level 0 and a logic level 1. The x-axis of the graph 602 includes multiple times t0, t1, t2, t3, t4, and t5.

A time interval between any two consecutive times on the x-axis of the graph 602 is the same. For example, a time interval between the times t0 and t1 is equal to a time interval between the times t1 and t2, and the time interval between the times t1 and t2 is equal to a time interval between the times t2 and t3. The time interval between times t3 and t4 is equal to a time interval between the times t2 and t3, and the time interval between times t4 and t5 is equal to a time interval between the times t3 and t4. The time t1 is consecutive to the time t0. Similarly, the time t2 is consecutive to the time t1, the time t3 is consecutive to the time t2, the time t4 is consecutive to the time t3, and the time t5 is consecutive to the time t4.

The clock signal 604 periodically transitions between the logic levels 0 and 1. For example, during a first half of a cycle 1 of the clock signal 604, the clock signal 604 is at the logic level 1. At the time t1, the clock signal 604 transitions from the logic level 1 to the logic level 0. During a second half of the cycle 1 of the clock signal 604, the clock signal 604 has the logic level 0. At the time t2, the clock signal 604 transitions from the logic level 0 to the logic level 1. During a first half of a cycle 2 of the clock signal 604, the clock signal 604 is at the logic level 1. At the time t3, the clock signal 604 transitions from the logic level 1 to the logic level 0. During a second half of the cycle 2 of the clock signal 604, the clock signal is at the logic level 0. At the time t4, the clock signal 604 transitions from the logic level 0 to the logic level 1.

The cycle 2 of the clock signal 604 is consecutive to the cycle 1 of the clock signal 604. For example, there are no other clock cycles between the cycles 1 and 2 of the clock signal 604. The cycle 1 occurs from the time to t0 the time t2 and the cycle 2 occurs from the time t2 to the time t4.

FIG. 6B is a diagram of an embodiment of a graph 606 to illustrate an embodiment of a digital pulsed signal 608 used in some embodiments. The graph 606 plots a logic level of the digital pulsed signal 608 on a y-axis and the time t on an x-axis. The y-axis of the graph 606 includes the logic levels 0, 1, and 2. The x-axis of the graph 606 includes the time t0, a time t0a, a time t0b, the time t1, the time t2, a time t2a, a time t2b, and the times t3 and t4. The time toa occurs between the times t0 and t0b, and the time t0b occurs between the times t0a and t1. Moreover, the time t2a occurs between the times t2 and t2b, and the time t2b occurs between the times t2a and t3. The digital pulsed signal 608 periodically transitions among a first state (S1), a second state (S2), and a third state (S0). For example, the digital pulsed signal 608 has the state S1, which is defined by the logic level 0, from the time t0 to the time t0a. To illustrate, during the state S1 of the digital pulsed signal 608, the digital pulsed signal 608 is at the logic level 0.

The digital pulsed signal 608 transitions from the logic level 0 to the logic level 1 at the time t0a. The state S2 of the digital pulsed signal 608 is defined by the logic level 1. To illustrate, during the state S2 of the digital pulsed signal 608, the digital pulsed signal 608 is at the logic level 1.

The digital pulsed signal 608 has the state S2 from the time t0a to the time t0b. At the time t0b, the digital pulsed signal 608 transitions from the state S2 to the state S0, which is defined by the logic level 2. To illustrate, during the state S0 of the digital pulsed signal 608, the digital pulsed signal 608 is at the logic level 2. The digital pulsed signal 608 has the state S0 from the time t0b to the time t2. At the time t2, the digital pulsed signal 608 transitions from the state S0 back to the state S1.

The digital pulsed signal 608 has the state S1 from the time t2 to the time t2a. The digital pulsed signal 608 transitions from the state S1 to the state S2 at the time t2a. The digital pulsed signal 608 has the state S2 from the time t2a to the time t2b. At the time t2b, the digital pulsed signal 608 transitions from the state S2 to the state S0. The digital pulsed signal 608 has the state S0 from the time t2b to the time t4. At the time t4, the digital pulsed signal 608 transitions from the state S0 back to the state S1.

It should be noted that multiple instances of each of the states S1, S2, and S0 of the digital pulsed signal 608 occur. For example, a first instance of the state S1 of the digital pulsed signal 608 occurs between the times t0 and t0a, and a second instance of the state S1 of the digital pulsed signal 608 occurs between the times t2 and t2a. As another example, a first instance of the state S2 of the digital pulsed signal 608 occurs between the times t0a and t0b, and a second instance of the state S2 of the digital pulsed signal 608 occurs between the times t2a and t2b. As yet another example, a first instance of the state S0 of the digital pulsed signal 608 occurs between the times t0b and t2, and a second instance of the state S0 of the digital pulsed signal 608 occurs between the times t2a and t4. As another example, the first instance of the state S2 of the digital pulsed signal 608 is consecutive to the first instance of the state S1 of the digital pulsed signal 608, and the first instance of the state S0 of the digital pulsed signal 608 is consecutive to the first instance of the state S2 of the digital pulsed signal 608. The second instance of the state S1 of the digital pulsed signal 608 is consecutive to the first instance of the state S0 of the digital pulsed signal 608. Also, the second instance of the state S2 of the digital pulsed signal 608 is consecutive to the second instance of the state S1 of the digital pulsed signal 608 and the second instance of the state S0 of the digital pulsed signal 608 is consecutive to the second instance of the state S2 of the digital pulsed signal 608.

FIG. 6C is an embodiment of a graph 610 of a primary RF signal 612 and a secondary RF signal 616 that are used in some embodiments. The primary RF signal 612 and secondary RF signal 614 are synchronized to the digital pulsed signal 608. For example, each of the primary RF signal 612 and secondary RF signal 614 initiate a transition from the state S1 to the state S2 at the time toa of the transition of the digital pulsed signal 608 from the state S1 to the state S2. As another example, each of the primary RF signal 612 and secondary RF signal 614 initiate a transition from the state S2 to the state S0 at the time t0b of the transition of the digital pulsed signal 608 from the state S2 the state S0. As yet another example, each of the primary RF signal 612 and secondary RF signal 614 initiate a transition from the state S0 to the state S1 at the time t2 of the transition of the digital pulsed signal 608 from the state S0 the state S1.

The graph 610 plots the power levels of the primary RF signal 612 and secondary RF signal 614. For example, the y-axis of the graph 610 includes power levels P0, P1, P2, P3, and P4. The power level P1 is greater than the power level PO. Also, the power level P2 is greater than the power level P1, and the power level P3 is greater than the power level P2. The power level P4 is greater than the power level P3. Also, the graph 610 plots the time t on an x-axis. For example, the x-axis of the graph 610 includes the times t0, t0a, t0b, t1, t2, t2a, t2b, t3, and t4.

A power level, as used herein, is an envelope, such as a peak-to-peak amplitude, of an RF signal. For example, a power level includes one or more peak-to-peak power values that are within a predetermined range from the power level, such as greater than or less than a value of the power level. As yet another example, the power level is a statistical value, such as an average or a median, of all the peak-to-peak power values of the power level. As another example, the power level is the highest of all peak-to-peak power values of the power level. As yet another example, the power level is the lowest of all peak-to-peak power values of the power level.

In an example used in some embodiments, the first state (S1) is from t0 to t0a, where the primary RF signal 612 is provided at a first primary power level of P4 and the secondary RF signal 614 is provided at a first secondary power level of P1, where P4 is greater than P1, as shown. The second state (S2) is from t0a to t0b, where the primary RF signal 612 is provided at a second primary power level of P2 and the secondary RF signal 614 is provided at a second secondary power level of P3, where P3 is greater than P2, as shown. The third state (S0) is from t0b to t2, where the primary RF signal 612 is provided at a third primary power level of 0, and the secondary RF signal 614 is provided at a third secondary power level of 0, as shown. In this example, during S0, the power level of the primary RF signal 612 is equal to the power level of the secondary RF signal 614, which is 0. More generally, in some embodiments, the third primary power level is about equal to the third secondary power level. More generally, in some embodiments, the absolute value of the difference between the third primary power level and the third secondary power level is less than both the absolute value of the difference between the first primary power and the first secondary power and the absolute value of the difference between the second primary power and the second secondary power.

It should be noted that in some embodiments, an RF signal, described herein, does not transition from one state to a consecutive state instantaneously. For example, a transition of the primary RF signal 612 from the state S1 to the state S2 is not instantaneous. To illustrate, the transition of the primary RF signal 612 from the state S1 to the state S2 occurs within the time window. As another example, a time window of transition from a time, as used herein, is a time period that occurs during a state after the time. To illustrate, the time window from the time toa is a time period that occurs during the state S2 of the digital pulsed signal 608 after the time toa. The time period after the time ta occurs during the state S2 of the digital pulsed signal 608 from the time t0a to a time between the times t0a and t0b.

The state S1 of the primary RF signal 612 between the times t0 and t0a is the first instance of the state S1 of the primary RF signal 612 and the state S1 of the primary RF signal 612 between the times t2 and t2a is a second instance of the state S1 of the primary RF signal 612. Similarly, the state S2 of the primary RF signal 612 between the times toa and t0b is the first instance of the state S2 of the primary RF signal 612, and the state S2 of the Primary RF signal 612 between the times t2a and t2b is a second instance of the state S2 of the Primary RF signal 612. Also, the state S0 of the primary RF signal 612 between the times t0b and t2 is the first instance of the state S0 of the primary RF signal 612, and the state S0 of the primary RF signal 612 between the times t2b and t4 is a second instance of the state S0 of the primary RF signal 612.

Similarly, the state S1 of the primary RF signal 612 between the times t0 and t0a is the first instance of the state S1 of the primary RF signal 612, and the state S of the primary RF signal 612 between the times t2 and t2a is a second instance of the state S1 of the primary RF signal 612. Similarly, the state S2 of the primary RF signal 612 between the times t0a and t0b is the first instance of the state S2 of the primary RF signal 612, and the state S2 of the primary RF signal 612 between the times t2a and t2b is a second instance of the state S2 of the primary RF signal 612. Also, the state S0 of the primary RF signal 612 between the times t0b and t2 is the first instance of the state S0 of the primary RF signal 612, and the state S0 of the primary RF signal 612 between the times t2b and t4 is a second instance of the state S0 of the primary RF signal 612.

In some embodiments, providing a higher power for the primary RF signal 612 during state S1 allows for an increased bias providing a higher aspect ratio etch. However, the higher bias power may cause negative effects, such as increased bowing, lower selectivity, clogging or necking, and faceting. In order to reduce or remove some of the negative effects of an increased bias power, state S2 is provided where the bias power provided by the primary RF signal 612 is reduced and the plasma source power provided by the secondary RF signal 614 is increased. In some embodiments, the power level of the secondary RF signal 614 is increased to be greater than the power level of the primary RF signal 612. In order to remove some of the negative effects that are not removed by state S2, a third state S0 is provided. Therefore, providing an etch of a stack with a silicon oxide layer below a mask that has an etch gas with a halogen containing component and a phosphorus containing component using a multi-state RF power that has at least three states provides an improved etch that is more selective with reduced negative effects. In some embodiments, the etch gas is free of metal containing components.

In some embodiments, in state S1 with a higher primary power level than secondary power level, a higher bias power is provided to provide a faster high aspect ratio etch. In some embodiments, the higher bias etch removes some of the mask and may also cause some sputtering that redeposits on the sides of the features causing some necking that may cause some clogging. In some embodiments, state S2 with a higher secondary power level and a lower primary power level allows for an increased plasma density with a lower bias allowing for the removal of any necking and clogging that is formed. In some embodiments, state S2 with a lower primary power level allows for a lower bias allowing for the removal of any necking and clogging that is formed. In some embodiments, 4 or more states are used, with two states S1 and S2 at substantially higher primary and secondary power compared to state S3 and including a state S0 with zero power. In some embodiments, during state S0, the power level of the primary RF signal 612 is about equal to the power level of the secondary RF signal 614. In some embodiments, during state S0, the power level of the primary RF signal 612 and the power level of the secondary RF signal 614 are each less than 300 watts. In some embodiments, during state S0, the power level of the primary RF signal 612 and the power level of the secondary RF signal 614 are zero watts. In some embodiments, the lower power levels for the primary RF signal 612 and secondary RF signal 614 cause a neutral deposition to deposit on the mask allowing for an increased etch selectivity by adding to the mask. In some embodiments, the duty cycle of the third state S0 is greater than the duty cycle of the first state S1 and the duty cycle of the second state S2 in order to provide a longer time for deposition on the mask to increase selectivity. In some embodiments, the duty cycle of the third state S0 is in the range of 25% to 94%. In some embodiments, state S0 may be before state S1. In some embodiments, state S0 may be between state S1 and state S2. In some embodiments, state S2 may be before state S1.

In some embodiments, a fourth state (S3) is used in the multi-state pulsing. The state S3 may be before or after state S1, state S2, or state S0. Some embodiments have more than four states. In some embodiments, one or more states have zero RF power.

In some embodiments, a first state (S1) has a high RF power, a second state (S2) has a mid RF power, and a third state (S0) has a low RF power, which is lower than the mid RF power. In some embodiments, the high RF power of the first state (S1) has a first primary power and a first secondary power, the mid RF power of the second state (S2) has a second primary power and a second secondary power, and the low RF power of the third state (S0) has a third primary power and a third secondary power. In some embodiments, the first primary power is greater than the second primary power, the second primary power is greater than the third primary power, the first secondary power is greater than the second secondary power, and the second secondary power is greater than the third secondary power. In some embodiments, the low RF power is 0 Watts, so that the third primary power and the third secondary power are 0 Watts.

In some embodiments, during the etch process as the etch features are etched deeper so that the height to width aspect ratios increase, the parameters of the states S1, S2, and S0 may change. For example, in some embodiments, the bias during S1 may increase over time. In some embodiments, the duty cycle for state S0 may increase over time. In some embodiments, the duty cycle of S2 may increase over time.

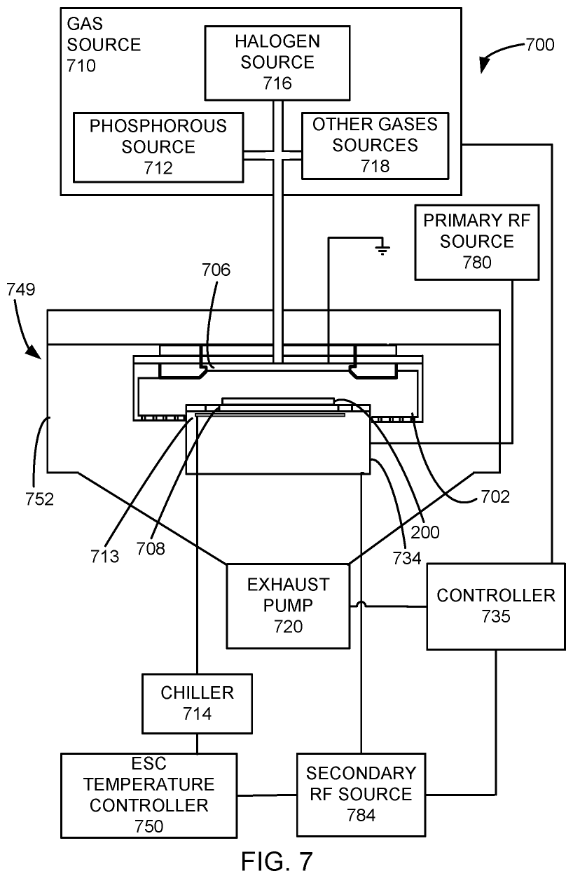

FIG. 7 is a schematic view of an etch reactor that may be used in some embodiments. In some embodiments, an etch reactor 700 comprises a gas distribution plate 706 providing a gas inlet and an electrostatic chuck (ESC) 708, within an etch chamber 749, enclosed by a chamber wall 752. Within the etch chamber 749, a stack 200 is positioned over the ESC 708, where the ESC 708 acts as a substrate support. An etch gas source 710 is connected to the etch chamber 749 through the gas distribution plate 706. In some embodiments, the etch gas source 710 comprises a phosphorus containing component source 712, a halogen containing component source 716, and a source of other gases 718, such as a hydrogen containing component source, and a fluorocarbon containing component source. An ESC temperature controller 750 is connected to a chiller 714. The chiller 714 is able to cool the ESC 708 to a temperature of less than 0 °C. In this embodiment, the chiller 714 provides a coolant to channels 713 in or near the ESC 708. A primary radio frequency (RF) power source 780 provides a primary RF signal to a lower electrode, which in this embodiment is the ESC 708. A secondary RF power source 784 provides a secondary RF signal to the ESC 708. The gas distribution plate 706 forms an upper electrode that is grounded. In some embodiments, at least one of a 400 kilohertz (kHz) power source and a 2 MHz power source may make up the primary RF power source 780. In some embodiments, at least one of a 60 MHz power source and a 27 MHz power source make up the secondary RF power source 784. Other arrangements of RF sources and electrodes may be used in other embodiments. A controller 735 is controllably connected to the primary RF power source 780 providing a primary signal, the secondary RF power source 784 providing a secondary signal, the ESC source 748, an exhaust pump 720, and the etch gas source 710.

Examples of such etch chambers are the Exelan Flex® dielectric etch system and Vantex® dielectric etch system manufactured by Lam Research Corporation of Fremont, CA. The etch chamber can be a CCP (capacitively coupled plasma) reactor or an ICP (inductively coupled plasma) reactor, where the electrode may be a coil.

In some embodiments, the controller 735 is configured to cool the substrate support to a temperature of no more than 0 °C, provide the etch gas comprising a halogen containing component from the halogen containing component source and a phosphorus containing component from the phosphorus containing component source, generate a plasma from the etch gas, and provide a bias to accelerate ions from the plasma to the stack.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A method for etching features in a stack comprising a silicon oxide layer below a mask, comprising:
cooling a substrate support for supporting the stack in an etch chamber to a temperature below 0 °C;
providing an etch gas comprising a halogen containing component and a phosphorus containing component;
generating a plasma from the etch gas;
providing a bias to accelerate ions from the plasma to the stack; and
selectively etching features in the stack with respect to the mask.

2. The method, as recited in claim 1, wherein the etch gas further comprises a hydrogen containing component.

3. The method, as recited in claim 1, wherein the mask is a carbon containing mask.

4. The method, as recited in claim 3, wherein the carbon containing mask is amorphous carbon.

5. The method, as recited in claim 1, wherein the etch gas is oxygen free and free from both C₄F₈ and C₄F₆.

6. The method, as recited in claim 1, wherein the halogen containing component, comprises at least one of a chlorohydrocarbon, bromofluorocarbon, chlorofluorocarbon, SiCl₄, BCl₃, NF₃, C₄F₈, C₃F₈, C₄F₆, SF₆, CF₄, Cl₂, HBr, CF₃I, CH₃F, CH₂F₂, CHF₃, and HCl.

7. The method, as recited in claim 1, wherein the etch gas further comprises at least one of HF, H₂, O₂, and CH₄.

8. The method, as recited in claim 1, wherein the cooling the substrate support for supporting the stack in an etch chamber to the temperature below 0 ° C, further comprises cooling the substrate support to a temperature below −10 °C.

9. The method, as recited in claim 1, wherein the mask is a carbon containing mask and the stack comprises a plurality of alternating layers of silicon oxide or silicon nitride.

10. The method, as recited in claim 1, further comprising providing an RF power with a peak power in a range of 3 kW to 150 kW.

11. The method, as recited in claim 1, wherein the phosphorus containing component comprises at least one of PF₅, PH₃, PF₃, PCl₃, PBr₃, POF₃, and PI₃.

12. The method, as recited in claim 1, wherein the phosphorus containing component comprises at least one of PH₃ and PF₃.

13. The method, as recited in claim 1, wherein the etch gas further comprises an inert gas comprising at least one of He, Ne, Ar, Kr, Xe, and N₂.

14. The method, as recited in claim 1, wherein the mask is a carbon containing mask and wherein the stack includes a plurality of alternating layers of silicon oxide and polysilicon.

15. The method, as recited in claim 1, wherein the features have a height to width ratio greater than 10:1.

16. The method, as recited in claim 1, wherein the phosphorus containing component comprises PF₅.

17. The method, as recited in claim 1, wherein the phosphorus containing component comprises at least one of PF₃ and PF₅, further comprising providing an RF power, wherein the RF power is continuous.

18. The method, as recited in claim 1, wherein the providing the bias provides a bias of greater than 200 volts.

19. The method, as recited in claim 1, wherein the bias is provided by a pulsed bias of at least two states.

20. The method, as recited in claim 1, wherein the bias is provided by an RF power source.

21. An apparatus for processing a stack over a substrate with at least one silicon oxide layer, comprising:
an etch chamber;
a substrate support for supporting a substrate inside the etch chamber;
a temperature controller for controlling a temperature of the substrate support;
a gas source that provides an etch gas, the gas source comprising:
a halogen containing component source; and
a phosphorus containing component source;
an electrode for providing power to the etch gas; and
a power source for providing power to the electrode.

22. The apparatus, as recited in claim 21, further comprising a controller controllably connected to the gas source, the power source, and the temperature controller, configured to:
cool the substrate support to a temperature of no more than 0 °C;
provide the etch gas comprising a halogen containing component from the halogen containing component source and a phosphorus containing component from the phosphorus containing component source;
generate a plasma from the etch gas; and
provide a bias to accelerate ions from the plasma to the stack.

23. The apparatus, as recited in claim 22, wherein the gas source further comprises a hydrogen containing component source.

24. The apparatus, as recited in claim 23, wherein the controller is further configured to provide a hydrogen containing component from the hydrogen containing component source.

25. The apparatus, as recited in claim 22, wherein the power source comprises:
a primary power source that provides a primary signal at a first frequency range; and
a secondary power source that provides a secondary signal at a second frequency range, wherein the controller is further configured to:
pulse the primary signal among at least three states including a first state, a second state, and a third state; and
pulse the secondary signal among the first state, the second state, and the third state.

26. The apparatus, as recited in claim 25,
wherein during the first state the primary signal has a first primary power level, and the secondary signal has a first secondary power level;
wherein during the second state, the primary signal has a second primary power level, and the secondary signal has a second secondary power level; and
wherein during the third state, the primary signal has a third primary power level and the secondary signal has a third secondary power level, wherein the first primary power level is greater than the second primary power level, the second primary power level is greater than the third primary power level, the first secondary power level is greater than the second secondary power level, and the second secondary power level is greater than the third secondary power level.

27. The apparatus, as recited in claim 25, wherein the primary signal is a primary RF signal, and the secondary signal is a secondary RF signal.

28. The apparatus, as recited in claim 25, wherein the wherein the primary signal is a primary pulsed bias signal, and the secondary signal is a secondary pulsed bias signal.

29. The apparatus, as recited in claim 21, wherein the power source is an RF power source.

30. The apparatus, as recited in claim 21, wherein the power source is a pulsed bias source.

31. A method for etching features in a stack comprising a silicon oxide layer below a mask, comprising:
cooling a substrate support for supporting the stack in an etch chamber to a temperature below 0 °C;
providing an etch gas comprising a halogen containing component and a phosphorus containing component;
providing a multi-state power with at least three states, wherein the multi-state power generates a plasma from the etch gas and provides a bias to accelerate ions from the plasma to the stack; and
selectively etching features in the stack with respect to the mask.

32. The method, as recited in claim 31, wherein the providing the multi-state power, comprises:
generating a primary signal, wherein the primary signal pulses among at least three states including a first state, a second state, and a third state; and
generating a secondary signal, wherein the secondary signal pulses among the first state, the second state, and the third state.

33. The method, as recited in claim 32,
wherein during the first state the primary signal has a first primary power level, and the secondary signal has a first secondary power level;
wherein during the second state, the primary signal has a second primary power level, and the secondary signal has a second secondary power level; and
wherein during the third state, the primary signal has a third primary power level and the secondary signal has a third secondary power level, wherein the first primary power level is greater than the second primary power level, the second primary power level is greater than the third primary power level, the first secondary power level is greater than the second secondary power level, and the second secondary power level is greater than the third secondary power level.

34. The method, as recited in claim 33, wherein the third primary power level and the third secondary power level are equal to 0 Watts.

35. The method, as recited in claim 33, wherein a duty cycle of the third state is greater than both a duty cycle of the first state and a duty cycle of the second state.

36. The method, as recited in claim 32, wherein the etch gas further comprises a hydrogen containing component.

37. The method, as recited in claim 32, wherein the mask is a carbon containing mask.

38. The method, as recited in claim 32, wherein the etch gas is oxygen free and free from both C₄F₈ and C₄F₆.

39. The method, as recited in claim 32, wherein the etch gas further comprises at least one of HF, H₂, O₂, and CH₄.

40. The method, as recited in claim 32, wherein the cooling the substrate support for supporting the stack in an etch chamber to a temperature below 0 °C, further comprises cooling the substrate support to a temperature below −10 °C.

41. The method, as recited in claim 32, wherein the mask is a carbon containing mask and the stack comprises a plurality of alternating layers of silicon oxide or silicon nitride.

42. The method, as recited in claim 32, wherein the phosphorus containing component comprises at least one of PF₅, PH₃, PF₃, PCl₃, PBr₃, POF₃, and PI₃.

43. The method, as recited in claim 32, wherein the etch gas further comprises an inert gas comprising at least one of He, Ne, Ar, Kr, Xe, and N₂.

44. The method, as recited in claim 32, wherein the mask is a carbon containing mask and wherein the stack includes a plurality of alternating layers of silicon oxide and polysilicon.

45. The method, as recited in claim 31, wherein the multi-state power provides RF power.

46. The method, as recited in claim 31, wherein the wherein the multi-state power provides a bias power.
